(19) United States
(12) Patent Application Publication
(10) Pub. No.: US 2024/0088084 A1
(43) Pub. Date: Mar. 14, 2024

(54) TIGHTLY-COUPLED RANDOM ACCESS MEMORY INTERFACE SHIM DIE

(71) Applicant: Micron Technology, Inc., Boise, ID (US)

(72) Inventors: Ameen D. Akel, Rancho Cordova, CA (US); Brent Keeth, Boise, ID (US)

(21) Appl. No.: 17/943,104

(22) Filed: Sep. 12, 2022

(51) Int. Cl. H01L 23/00; H01L 23/48; H01L 25/00; H01L 25/065

(52) U.S. Cl. CPC H01L 24/24; H01L 23/481; H01L 24/08; H01L 24/16; H01L 24/73; H01L 25/0657; H01L 25/50; H01L 2224/08146; H01L 2224/16145; H01L 2224/16245; H01L 2224/24145; H01L 2224/73259; H01L 2225/06513; H01L 2225/06517; H01L 2225/06527; H01L 2225/06544; H01L 2924/1433; H01L 2924/1436

(57) ABSTRACT

An interface shim layer for a tightly-coupled random access memory device is disclosed. The interface shim layer redirects and coalesces integrated channels and connections between a stacked plurality of memory die and an application specific integrated circuit and directly connects to the memory die and to the application specific integrated circuit. A passive version of the interface shim layer incorporates a plurality of routing layers to facilitate routing of signals to and from the stacked plurality of memory die and the application specific integrated circuit. An active version of the interface shim layer incorporates separate physical interfaces for both the stacked plurality of memory die and the application specific integrated circuit to facilitate routing. The active version of the interface shim layer may further incorporate memory controller functions, built-in self-test circuits, among other capabilities that are migratable into the active interface shim layer.

### FIELD OF THE TECHNOLOGY

At least some embodiments disclosed herein relate to memory devices in general, and more particularly, but not limited to, tightly-coupled random access memory interface shim die.

### BACKGROUND

Typically, a computing device or system includes one or more processors and one or more memory devices, such as memory chips or integrated circuits. The memory devices may be utilized to store data that may be accessed, modified, deleted, or replaced. The memory devices may be, for example, non-volatile memory devices that retain data irrespective of whether the memory devices are powered on or off. Such non-volatile memories may include, but are not limited to, read-only memories, solid state drives, and NAND flash memories. Additionally, the memory devices may be volatile memory devices, such as, but not limited to, dynamic or static random-access memories, which retain stored data while powered on, but are susceptible to data loss when powered off. Based on receipt of an input, the one or more processors of the computing device or system may request that a memory device of the computing system retrieve stored data associated with or corresponding to the input. In certain scenarios, the data retrieved from the memory device may include instructions, which may be executed by the one or more processors to perform various operations and may include data that may be utilized as inputs for the various operations. In instances where the one or more processors perform operations based on instructions from the memory device, data resulting from the performance of the operations may be subsequently stored into the memory device for future retrieval.

To meet the ever-increasing desire for high performance memory, various implementations of high-bandwidth memory have been developed. High-bandwidth memory provides a high-speed computer memory interface for vertically-stacked random-access memory dies and is utilized for a variety of different purposes. For example, an exemplary high-bandwidth memory implementation may include stacking a plurality of memory dies on top of a base die, which can include testing logic to test the operative functionality of the memory device and buffer circuitry to provide buffering capabilities. In exemplary scenarios, the stack of memories dies may be connected to a memory controller on a central processing unit or graphics processing unit. In other exemplary scenarios, the stack of random access memories may be stacked directly onto the central processing unit or graphics processing unit. In order to facilitate communication between the stacked random-access memory dies and an application specific integrated circuit resident in the same package, silicon interposer layers may be utilized to provide a channel for communications between the stack random-access memory dies and the application specific integration circuit. Despite the benefits provided by existing high-bandwidth memory technologies, high-bandwidth and other memory technologies may enhanced to provide even greater bandwidth, superior memory energy per bit, less invasive integration, among other benefits.

### BRIEF DESCRIPTION OF THE DRAWINGS

The embodiments are illustrated by way of example and not limitation in the figures of the accompanying drawings in which like references indicate similar elements.

FIG. 1 illustrates a schematic diagram of a system including a memory device, an interface shim layer, an application specific integrated circuit, and a package substrate in accordance with embodiments of the present disclosure.

FIG. 2 illustrates a schematic diagram featuring the system of FIG. 1 and various exemplary technical specifications of the system in accordance with embodiments of the present disclosure.

FIG. 3, illustrates an exemplary tightly-controlled random access memory for use in a stacked memory of the system of FIG. 1 in accordance with embodiments of the present disclosure.

FIG. 4 illustrates further detail relating to the tightly-controlled random access memory of FIG. 3 in accordance with embodiments of the present disclosure.

FIG. 5 illustrates an exemplary passive interface shim layer implementation according to embodiments of the present disclosure.

FIG. 6 illustrates an exemplary active interface shim layer implementation according to embodiments of the present disclosure.

FIG. 7 illustrates a method for creating a memory device including an interface shim layer in accordance with embodiments of the present disclosure.

FIG. 8 illustrates a schematic diagram of a machine in the form of a computer system within which a set of instructions, when executed, may cause the machine to facilitate functionality supporting a memory device including an interface shim layer according to embodiments of the present disclosure.

### DETAILED DESCRIPTION

The following disclosure describes various embodiments for systems and methods for providing a tightly-coupled random access memory interface shim layer or die for a memory device, such as a 3D memory device package. At least some embodiments of the present disclosure relate to memory device technologies for relocating and coalescing connections and channels between a tightly-coupled random access memory stack supporting high-bandwidth memory capabilities and an application specific integrated circuit into the interface shim layer. Additionally, at least some embodiments relate to memory device technologies for reducing the footprint of componentry in a memory device package. For example, embodiments described herein enable the stacking of stacked memory die directly onto the unique interface shim layer, which may directly connect to an application specific integrated circuit. At least some embodiments of the present disclosure provide technological enhancements for reducing or avoiding direct integration of communication interface componentry within application specific integrated circuits that may be supplied by a customer of the memory device. For example, the interface shim layer disclosed herein may be combined with a plurality of stacked memory die in a package that may be provided to a customer. The customer may then directly connect (e.g., via using soldering balls or other connection mechanisms) the customer's application specific integrated circuit onto the interface shim layer, which may remain separate from the application specific integrated circuit. The interface shim layer and the functionality that it supports may also remove the need for a silicon interposer layer to enable communication between an application specific integrated circuit and stacked memory die.

In accordance with embodiments of the present disclosure, a passive interface shim layer for a memory device is disclosed. In certain embodiments, the memory device may include a plurality of stacked memory die, a passive interface shim layer, an application specific integrated circuit, and a package substrate. The passive interface shim layer may be configured to directly couple to at least one memory die of the plurality of stacked memory die of the memory device. In certain embodiments, the interface shim layer may be configured to directly couple to the application specific integrated circuit, such as via bumps or other connection mechanisms. In certain embodiments, the interface shim layer may be configured to facilitate communication and signal routing between the plurality of stacked memory die and the application specific integrated circuit, such as via one or more routing layers of the passive interface shim layer (or die). In certain embodiments, bumps and bump pitches utilized for connecting the componentry of the memory device may be modified as desired and the bumps may be located at any desired distance with respect to each other within the memory device, such as to optimize connectivity and compatibility with the application specific integrated circuit and stacked memory die. In certain embodiments, the passive interface shim layer may be configured to communicate with a connected application specific interface circuit using through-silicon vias extending through the application specific integrated circuit and connecting to a physical interface layer of the application specific integrated circuit. The passive interface shim layer may be configured to communicate with connected stacked memory die by utilizing through-silicon vias connected to the stacked memory die.

In accordance with embodiments of the present disclosure, an active interface shim layer for a memory device is disclosed. In certain embodiments, the memory device may include a plurality of stacked memory die, an active interface shim layer, an application specific integrated circuit, and a package substrate. The active interface shim layer may be configured to directly couple to at least one memory die of the plurality of stacked memory die of the memory device. In certain embodiments, the active interface shim layer may be configured to directly couple to the application specific integrated circuit, such as via bumps or other connection mechanisms. In certain embodiments, the active interface shim layer may be configured to facilitate communication and signal routing between the plurality of stacked memory die and the application specific integrated circuit, such as via one or more routing layers of the active interface shim layer (or die) and via a tightly-coupled random access memory physical interface layer and an application specific integrated circuit physical interface layer, both of which may reside within the active interface shim layer. In certain embodiments, bumps and bump pitches utilized for connecting the componentry of the memory device may be modified as desired and the bumps may be located at any desired distance with respect to each other within the memory device, such as to optimize connectivity and compatibility with the application specific integrated circuit and stacked memory die. The application specific integrated circuit may be connected to a package substrate (e.g., silicon) via any number of bumps or other connection mechanisms.

In certain embodiments, the active interface shim layer may be configured to communicate with a connected application specific interface circuit using the application specific integrated circuit physical interface layer and using through-silicon vias extending through the application specific integrated circuit and connecting to a physical interface layer of the application specific integrated circuit. In certain embodiments, the active interface shim layer may be configured to communicate with connected stacked memory die by utilizing the tightly-coupled random access memory physical interface layer and connected through-silicon vias that are connected to the stacked memory die. In certain embodiments, any types of functions and features may be incorporated into the active shim interface layer. For example, memory controller functions, built-in self-test circuits, various physical interface layers (PHYs), input output circuits, any other componentry, or a combination thereof may be incorporated into the action interface shim layer. Based on at least the foregoing, the systems and methods of the present disclosure provide a unique tightly-coupled memory interface shim layer or die to facilitate relocation of connections from stacked memory die and application specific integrated circuits, while also ensuring strong memory performance, reduced application specific integrated circuit complexity, and improved communication capabilities among the componentry of a memory device incorporating the interface shim layer or die.

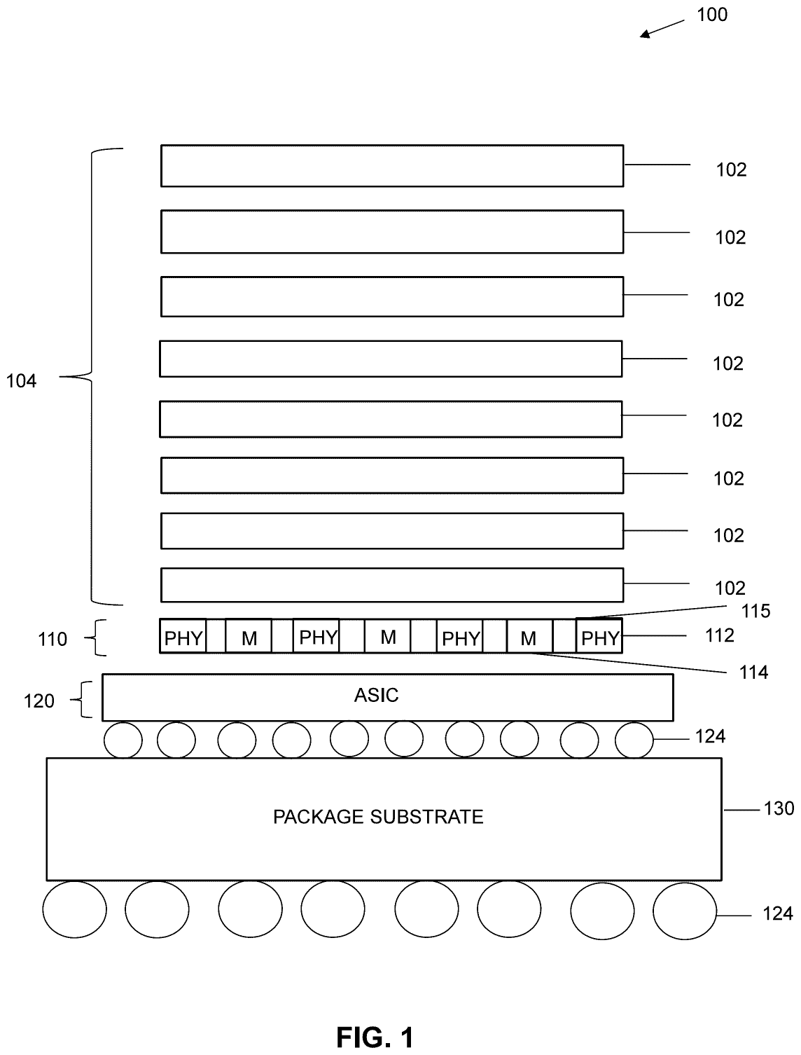

Referring now also to FIG. 1, FIG. 1 illustrates a schematic diagram of a system 100 (e.g., a memory device system) including a stacked memory die 104 (e.g., stacked memory device including memory die 102 stacked on top of each other), an interface shim layer 110, an application specific integrated circuit 120, a function layer 115, and a package substrate 130 in accordance with embodiments of the present disclosure. The stacked memory die 104 and other componentry illustrated in the Figures may belong to the system 100. In certain embodiments, the stacked memory die 104 and memory dies 102 may include, for example, but are not limited to, DRAM, high-bandwidth memory, an SSD, eMMC, memory card, or other storage device, or a NAND-based flash memory chip or module that is capable of encoding and decoding stored data, such as by utilizing an encoder and decoder of the system 100, or any combination thereof. In certain embodiments, the system 100 may include any amount of componentry to facilitate the operation of the system 100. In certain embodiments, for example, the stacked memory die 104 may include, but is not limited to including, a non-volatile memory, which may include any number of memory blocks, a volatile memory such as DRAM, physical interface layers 112, an interface shim layer 110, memory controllers 114 (which may include the encoder and a decoder), a hardware security module, any other componentry, or a combination thereof. The memory device stacked memory die 104 may communicatively link with an application specific integrated circuit 120 configured to interact with the stacked memory die 104, such as via the interface shim layer 110. In certain embodiments, the stacked memory die may couple with and communicate with a host device, which may be or include a computer, server, processor, autonomous vehicle, any other computing device or system, or a combination thereof.

In certain embodiments, the stacked memory die 104 may be configured to retain stored data irrespective of whether there is power delivered to the stacked memory die 104. In certain embodiments, the stacked memory die 104 may be configured to include any number of memory blocks that may be configured to store user data, any other type of data, or a combination thereof. In certain embodiments, the stacked memory die 104 may be configured to include a plurality of physical memory cells configured to store data. In certain embodiments, stacked memory die 104 may include an array of bit cells, each of which may be configured to store a bit of data. In certain embodiments, each bit cell may be connected to a wordline and bitline. In certain embodiments, the memory cells of the stacked memory die 104 may be etched onto the silicon wafer (e.g., package substrate 130) forming the base of the system 100. In certain embodiments, the memory cells may be etched in an array of columns (e.g., bitlines) and rows (e.g., wordlines). In certain embodiments, the intersection of a particular bitline with a wordline may serve as the address of the memory cell. In certain embodiments, for each combination of address bits, the stacked memory device 104 may be configured to assert a wordline that activates the bit cells in a particular row. For example, in certain embodiments, when the wordline is high, the store bit may be configured to transfer to or from the bitline. On the other hand, in certain embodiments, when the wordline is not high, the bitline may be disconnected from the cell.

In certain embodiments, the interface shim layer 110 may be configured to connections, input output circuits, communication channels, or a combination thereof, that may ordinarily reside in the memory die 102, the application specific integrated circuit, or a combination thereof. In certain embodiments, the interface shim layer 110 may include componentry 115, which may include routing layers configured to facilitate routing of signals to and from the stacked memory die 104 and the application specific integrated circuit 120. In certain embodiments, the componentry 115 may include built-in self-test circuits, controllers, error correction functions, any type of functions, or a combination thereof. In certain embodiments, the interface shim layer 110 may include any number of physical interface layers 112 (PHYs), which may be configured to include input output circuits that communicate with the stacked memory die 104 and the application specific integrated circuit 120. In certain embodiments, the interface shim layer 110 may be configured to include any number of memory controllers 114, which may be configured to manage communication with the stacked memory die 104 and control the stacked memory die 104, such as via signals emanating from the application specific integrated circuit 120. In certain embodiments, the memory controllers 114 may be configured to include functions supporting schedulers and queueing, timing control, refresh management, data first-in first-outs (FIFOs), error correction capabilities, RAS features, floor sweeping, any other functions, or a combination thereof.

In certain embodiments, the application specific integrated circuit 120 may be coupled to the interface shim layer 110, such as via solder balls, bumps, other connection mechanisms, or a combination thereof. In certain embodiments, the application specific integrated circuit 120 may be coupled to a package substrate (e.g., silicon) via solder balls, bumps, other connection mechanisms, or a combination thereof. In certain embodiments, the stacked memory die 104 and the interface shim layer 110 may be formed and connected together by a manufacturer, who may then sell the combination to a customer. The customer may then integrate the combination of the stacked memory die 114 and the interface shim layer 110 with an application specific integrated circuit 120 or potentially other device. In certain embodiments, the interface shim layer 110 may be configured to be a passive interface shim layer or an active interface shim layer, the capabilities and features for which are further discussed in the present disclosure.

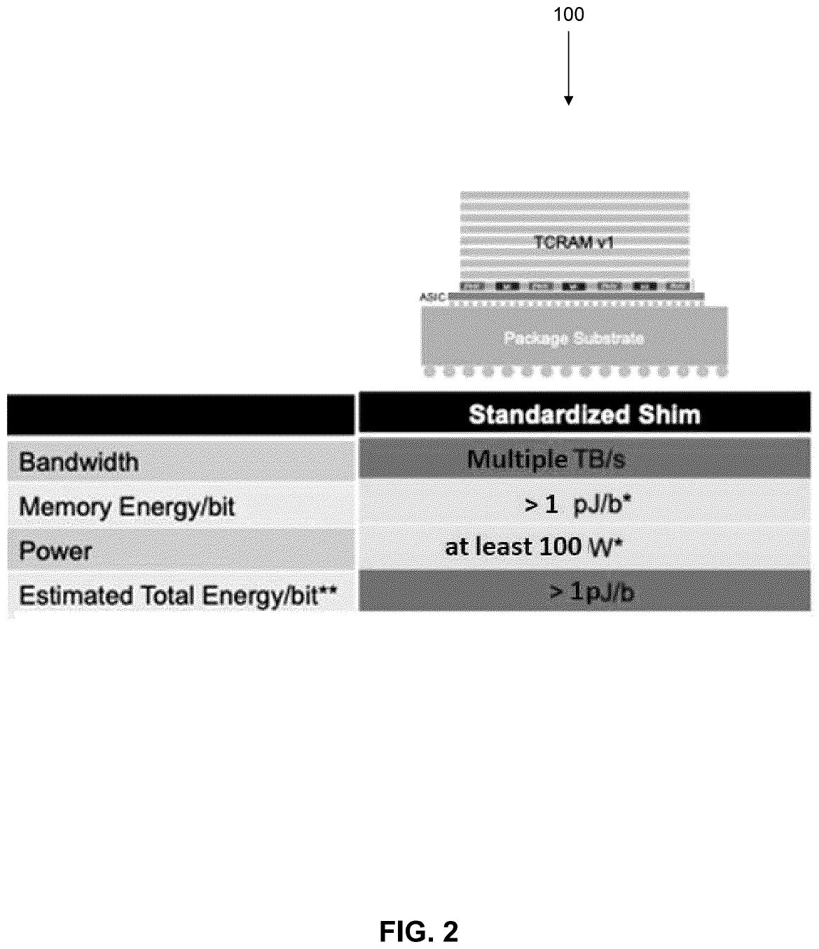

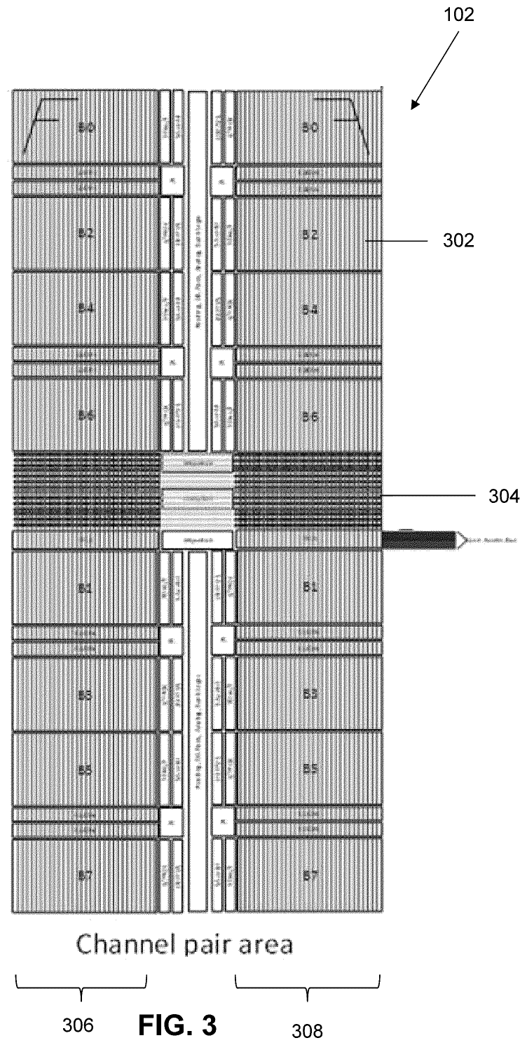

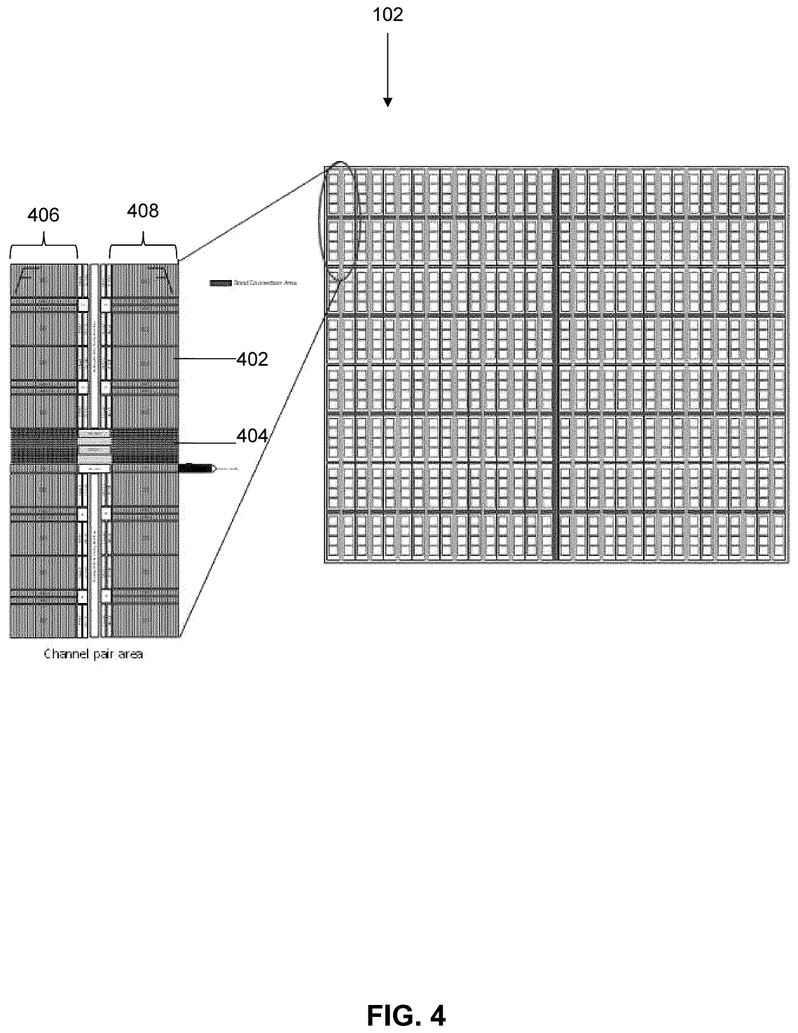

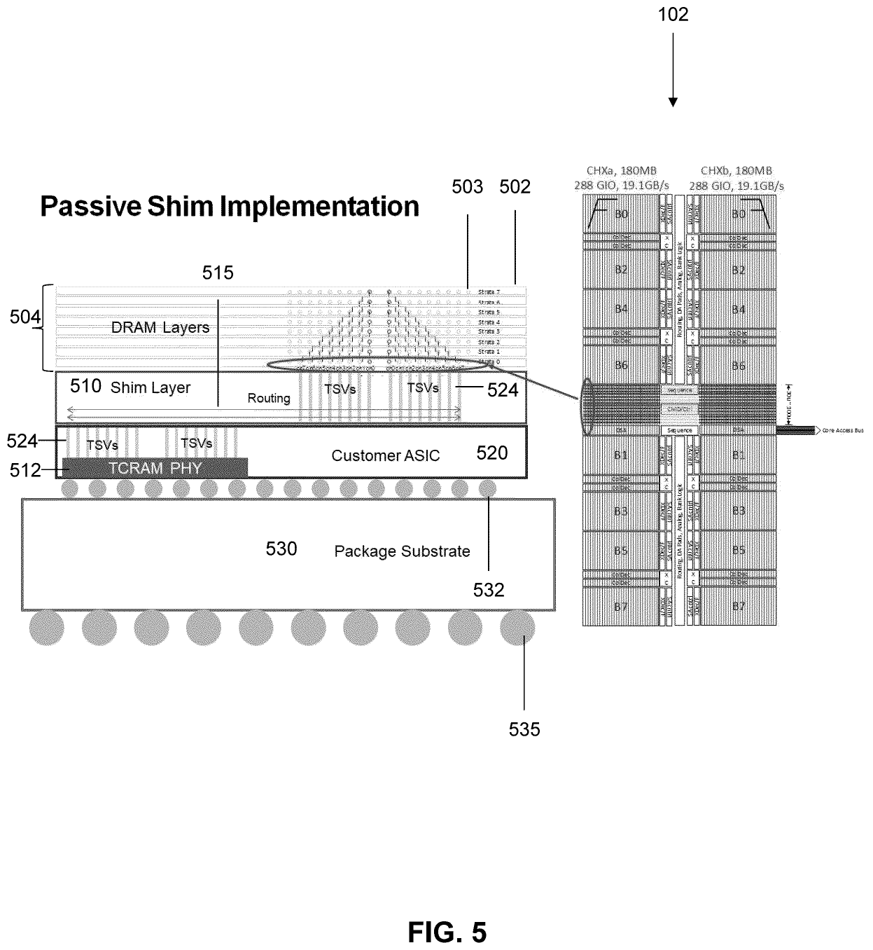

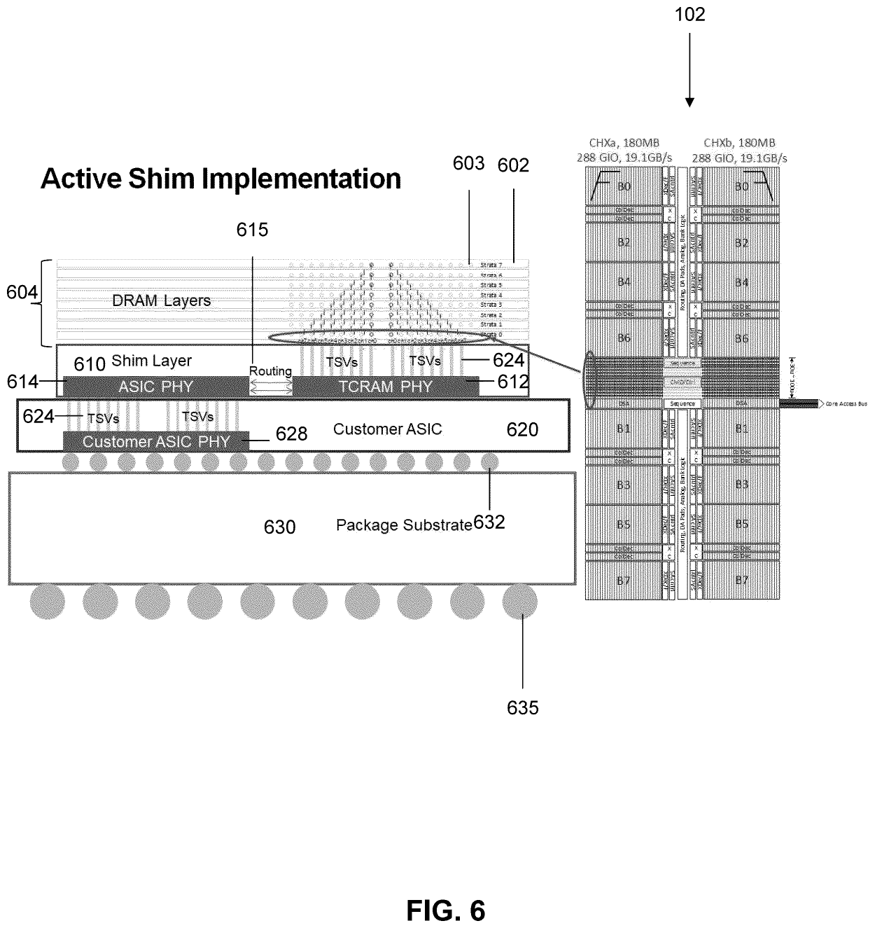

Referring now also to FIG. 2, a schematic diagram featuring the system of FIG. 1 and various exemplary technical specifications of interface shim layer 110 of the system 100 in accordance with embodiments of the present disclosure is illustrated. For example, the interface shim layer 110 may include supporting bandwidth for communications and signaling in at least the multiple TB/s range. As another example, the interface shim layer 110 may be configured to support greater than 1 pJ/b (i.e., memory energy per bit). As a further example, the interface shim layer 110 may be configured to support greater than 1 pJ/b (i.e., estimated total energy per bit). Referring now also to FIG. 3, an exemplary 128 channel tightly-coupled random access memory die (e.g., memory die 502 or memory die 602 in FIGS. 5 and 6 respectively) is shown. In certain embodiments, any number of memory die may be stacked on the memory device 102. In certain embodiments, the memory die may include a channel pair 306, 308 including eight banks 302 each. In certain embodiments, the memory die may include a plurality of through-silicon vias and bumps in section 304 to facilitate interaction between the memory die of the memory device 102. Referring now also to FIG. 4, further detail relating to an exemplary 128 channel tightly-coupled random access memory die (e.g. memory die 502 or memory die 602 in FIGS. 5 and 6 respectively) of a memory device 102 is shown. In certain embodiments, any number of memory die may be stacked on the memory device 102. In the exemplary embodiment illustrated in FIG. 4, the memory die may include a channel pair 406, 408 including eight banks 402 each. In certain embodiments, the memory die may include a plurality of through-silicon vias and bumps in section 404 to facilitate interconnection between the memory die of the memory device 102. In certain embodiments, the bumps, for example, may reside between each memory die layer within the stack of the memory device 102. Illustratively, on the right side of FIG. 4, 128 channels are illustrated for a single memory die of the memory device 102.

Referring now also to FIG. 5, an exemplary passive interface shim layer implementation according to embodiments of the present disclosure is schematically illustrated. FIG. 5 illustrates an exemplary memory device 102 (e.g., a tightly-coupled random access memory) (or stacked memory die 104) including various componentry to support the functionality of the memory device 102. In certain embodiments, the memory device 102 may include, but is not limited to including, a plurality of memory die 502 that when stacked on top of each other form a stacked memory die 504, an interface shim layer 510, an application specific integrated circuit physical interface layer 512, routing layers 515, through-silicon vias 524, an application specific integrated circuit 520, a package substrate 530, bumps (or solder balls) 532, 535. Illustratively, the stacked memory die 504 includes eight memory die 502, however, the stacked memory die 504 may include any number of memory die 502. In certain embodiments, the memory die 502 may be any type of memory die including, but not limited to, volatile memory die, such as dynamic random access memory (DRAM). In certain embodiments, the memory die 502 may be connected to each other within the stack by utilizing any number of bumps 503 (e.g., micro bumps, solder balls, etc.). Any suitable bump pitches (e.g., distance between bumps may be 6 μm) may be utilized for the bumps and any suitable bump locations may be utilized as well, such as to ensure compatibility with an application specific integrated circuit 520. In certain embodiments, the bumps 503 may form a dense bump grid within the stacked memory die 504.

In certain embodiments, the passive interface shim layer 510 may be configured to serve as an intermediary layer between the stacked memory die 504 and the application specific integrated circuit 520. In certain embodiments, connections and circuits (e.g., input output circuits) that may normally reside within the stacked memory die 504, the application specific integrated circuit 520, or both, may be migrated into and configured to reside or coalesce within the passive interface shim layer 510. In certain embodiments, the passive interface shim layer 510 may further include any number of routing layers 515. In certain embodiments, the routing layers 515 may be configured to facilitate routing of signals between the stacked memory die 504 and an application specific integrated circuit 520. In certain embodiments, the routing layers 515 may be connected to through-silicon vias 524 connected to the stacked memory die 504 and to through-silicon vias 524 extending into the application specific integrated circuit 520 and connected to a tightly-coupled random access memory physical interface layer 512 of the application specific integrated circuit 520. In certain embodiments, the routing layers 515 may be made of metals, any other suitable materials, or a combination thereof. In certain embodiments, the passive interface shim layer 510 may include any number of through-silicon vias 524 that may extend through the height of the active interface shim layer 510 may be configured to enable communication through the stacked memory die 504, as shown in FIG. 5.

In certain embodiments, the application specific integrated circuit 520 may be supplied by a customer of the memory device 102 manufacturer. For example, the customer may purchase the stacked memory die 504 and passive interface shim layer 510 as a connected combination and may connect the application specific integrated circuit 520 to the passive interface shim layer 510, such as via bumps (e.g., solder balls) or other componentry to secure the application specific integrated circuit 520 to the passive interface shim layer 510. The application specific integrated circuit 520 may comprise any type of application specific integrated circuit configured for any type of purpose. In certain embodiments, the application specific integrated circuit 520 may be connected to the to a package substrate 530 via a plurality of solder balls 532. In certain embodiments, the package substrate 530 may also be connected to solder balls 535 that may be utilized to connect the package substrate 530 to a package or potentially to another device. In certain embodiments, the memory device 102 incorporating the passive interface shim layer 510 may incorporate any of the componentry and functionality described for other embodiments of the memory device 102 or as otherwise described for memory devices described herein.

Referring now also to FIG. 6, an exemplary active interface shim layer implementation according to embodiments of the present disclosure is schematically illustrated. FIG. 6 illustrates an exemplary memory device 102 (e.g., a tightly-coupled random access memory) (or stacked memory die 104) including a plurality of componentry. In certain embodiments, the memory device 102 may include, but is not limited to including, a plurality of memory die 602 that when stacked on top of each other form a stacked memory die 604, an interface shim layer 610, an application specific integrated circuit physical interface layer 614, a tightly-coupled physical interface layer 612, routing layers 615, through-silicon vias 624, an application specific integrated circuit 620, a package substrate 630, bumps 635. Illustratively, for example, the stacked memory die 604 includes eight memory die 602, however, the stacked memory die 604 may include any number of memory die 602. In certain embodiments, the memory die 602 may be any type of memory die including, but not limited to, volatile memory die, such as dynamic random access memory (DRAM). In certain embodiments, the memory die 602 may be connected to each other within the stack by utilizing any number of bumps 603 (e.g., micro bumps, solder balls, etc.). Any suitable bump pitches (e.g., distance between bumps may be 6 μm) may be utilized for the bumps and any suitable bump locations may be utilized as well, such as to ensure compatibility with an application specific integrated circuit 620. In certain embodiments, the bumps 603 may form a dense bump grid within the stacked memory die 604.

In certain embodiments, the active interface shim layer 610 may be configured to serve as an intermediary between the stacked memory die 604 and the application specific integrated circuit 620. In certain embodiments, connections and circuits (e.g., input output circuits) that may ordinarily reside within the stacked memory die 604, the application specific integrated circuit 620, or both, may be configured to reside or coalesce within the active interface shim layer 610. In certain embodiments, the active interface shim layer 610 may include a tightly-coupled physical interface layer 612. In certain embodiments, the tightly-coupled physical interface layer 612 may include any number input output circuits (e.g., I/O circuits) that may be configured to communicate with the stacked memory die 604. In certain embodiments, the pin locations for the tightly-coupled physical interface layer 612 may be predefined. In certain embodiments, the active interface shim layer 610 may also include an application specific integrated circuit interface layer 614. In certain embodiments, the application specific integrated circuit interface layer 614 may be configured to include any number of input output circuits (e.g., I/O circuits) that are configured to communicate with the application specific integrated circuit 620 (e.g., a customer ASIC). As with the pins of the tightly-coupled physical interface layer 612, the application specific integrated circuit interface layer 614 may include pin locations that may be predefined as well.

In certain embodiments, the active interface shim layer 610 may further include any number of routing layers 615. In certain embodiments, the routing layers 615 may be configured to facilitate routing of signals between the tightly-coupled physical interface layer 612 and the application specific integrated circuit physical interface layer 614. In certain embodiments, the routing layers 615 may be connected to both the tightly-coupled physical interface layer 612 and the application specific integrated circuit physical interface layer 614. In certain embodiments, the routing layers 615 may be made of metals, any other suitable materials, or a combination thereof. In certain embodiments, the active interface shim layer 610 may include any number of through-silicon vias 624 that may extend through the height of the active interface shim layer 610 may be configured to enable communication through the stacked memory die 604, as shown in FIG. 6. In certain embodiments, a plurality of through-silicon vias 624 may connect and communicate with the tightly-coupled physical interface layer 612. Additionally, in certain embodiments, the active interface shim layer 610 may be configured to communicate with the application specific integrated circuit 620 via through-silicon vias 624 extending through the application specific integrated circuit 620 and connecting to an application specific integrated circuit physical interface layer 628, as shown in FIG. 6.

In certain embodiments, the application specific integrated circuit 620 may be supplied by a customer of the memory device 102 manufacturer. For example, the customer may purchase the stacked memory die 604 and active interface shim layer 610 as a connected combination and may connect the application specific integrated circuit 620 to the active interface shim layer 610, such as via bumps (e.g., solder balls) or other componentry to secure the application specific integrated circuit 620 to the active interface shim layer 610. The application specific integrated circuit 620 may comprise any type of application specific integrated circuit configured for any type of purpose. In certain embodiments, the application specific integrated circuit 620 may be connected to a package substrate 630 via a plurality of solder balls 632. In certain embodiments, the package substrate 630 may also be connected to solder balls 635 that may be utilized to connect the package substrate 630 to a package or potentially to another device. In certain embodiments, the memory device 102 incorporating the active interface shim layer 610 may incorporate any of the componentry and functionality described for other embodiments of the memory device 102 or as otherwise described for memory devices described herein.

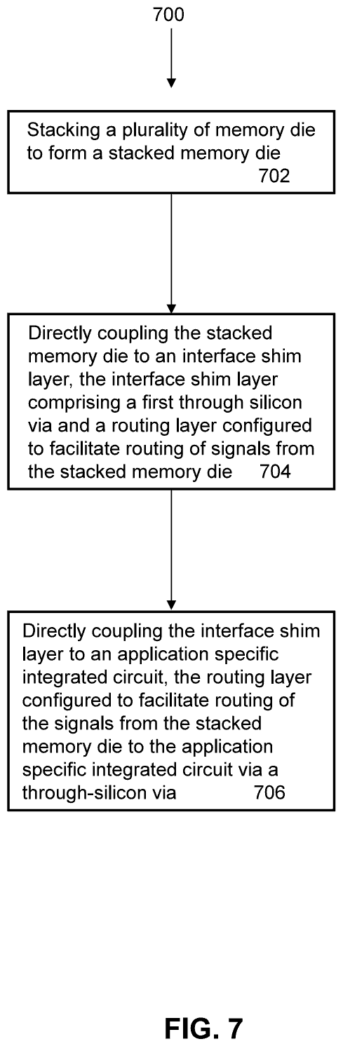

Referring now also to FIG. 7, FIG. 7 illustrates an exemplary method 700 for forming a memory device or system incorporating an interface shim layer or die (e.g., interface shim layer 110) according to embodiments of the present disclosure. Although shown in a particular sequence or order, unless otherwise specified, the order of the process(es) may be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible. For example, the method 700 may be modified to include steps describing how the interface shim layer 110 is utilized as an intermediary for communications between the stacked memory die 104 and the application specific integrated circuit 120.

The method 700 may include steps for creating a memory system, memory device, or computing device incorporating an interface shim layer (e.g., interface shim layer 110) according to various embodiments of the present disclosure. In certain embodiments, the method 700 may be utilized to create a passive interface shim layer 510, an active interface shim layer 610, or a combination thereof. In certain embodiments, the method 500 may be performed by utilizing the system 100, by utilizing any combination of the componentry contained therein, a manufacturing facility, or a combination thereof. At step 702, the method 700 may include stacking a plurality of memory die to form a stacked memory die. For example, each memory die 102 of the plurality of memory die 102 may be stacked on top of each other to create the stacked memory die 104. In certain embodiments, the stacked memory die 104 may be densely packed together and may be configured to communication with each other via through-silicon vias. For example, the through-silicon vias may comprise vertical electrical connections that pass completely through each of the memory die 102 of the stacked memory die 104, such as if the package including the stacked memory die 104 is to be a 3D package or 3D integrated circuit (e.g., metal-oxide semiconductor or semiconductor material). In certain embodiments, the through-silicon vias may be utilized instead of using wire-bonding or flip chips, however, in certain embodiments, such componentry may be incorporated as desired.

At step 704, the method 700 may include directly coupling the stacked memory die 104 to an interface shim layer (e.g., interface shim layer 110, 510, 610). In certain embodiments, the interface shim layer may include any number of through-silicon vias to facilitate communication with the stacked memory die 104. In certain embodiments, the interface shim layer may also include one or more routing layers (e.g., metal routing layers) to facilitate routing of signals (e.g., communications) from or to the stacked memory die 104, such as signals emanating from the stacked memory die 104 or signals emanating from an application specific integrated circuit 120 seeking to communicate with the stacked memory die 104. At step 706, the method 700 may include directly coupling the interface shim layer to an application specific integrated circuit (e.g., application specific integrated circuit 120). In certain embodiments, the routing layer(s) of the interface shim layer may be utilized to facilitate routing of signals received from the application specific integrated circuit, such as via a physical interface of the application specific integrated circuit and via through-silicon vias. In certain embodiments, such as in embodiments utilizing an active interface shim layer, the interface shim layer may include additional functions and componentry. For example, in an active interface shim layer, the interface shim layer may include, but is not limited to including, memory controllers, physical interfaces, built-in self-testing circuits, signal pins, channels, input output circuits, pins, any other componentry, or a combination thereof. In certain embodiments, the build-in self-test circuits may be utilized to facilitated at-speed testing and repair of memory elements. The memory controllers, for example, may be configured to manage communication with and control of the stacked memory die, including providing schedulers and queueing, timing control, memory refresh management, data FIFOs, error correction code capability, RAS (reliability, accessibility, and serviceability), floor sweeping, other functionality, or a combination thereof.

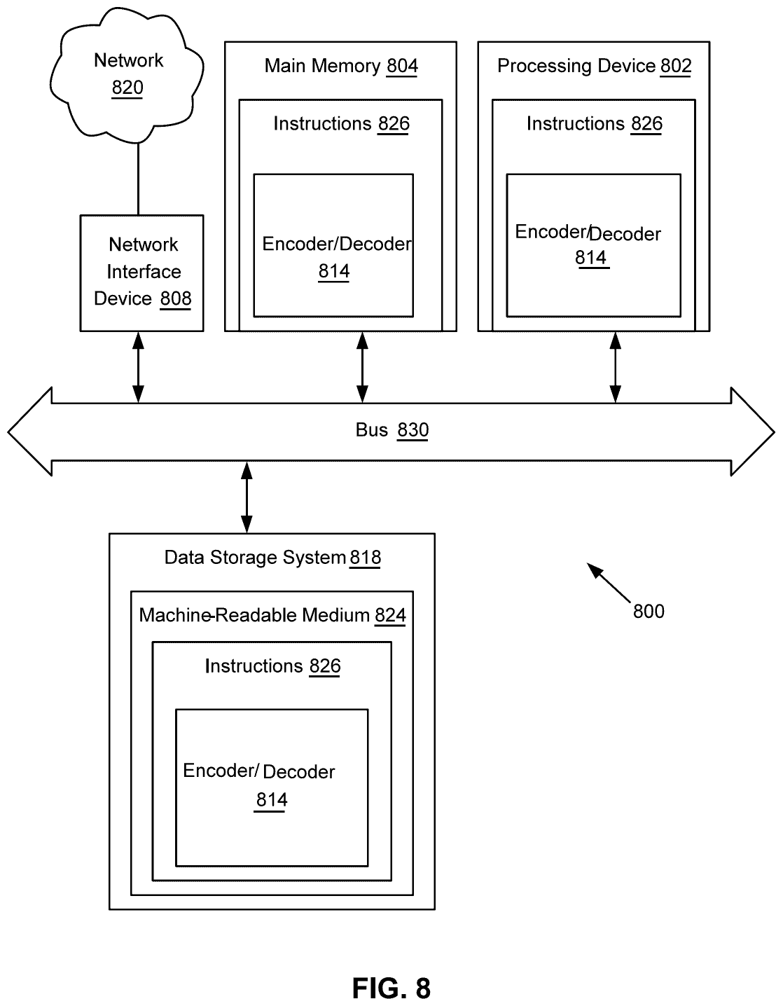

FIG. 8 illustrates an exemplary machine of a computer system 800 within which a set of instructions, for causing the machine to perform any one or more of the methodologies discussed herein, can be executed. In certain embodiments, the computer system 800 can correspond to a host system or device (e.g., a host device capable of communicating with the system 100, stacked memory device 104, the application specific integrated circuit 120, or other devices) that includes, is coupled to, or utilizes a memory system (e.g., the system 100 of FIG. 1). In certain embodiments, computer system 800 corresponds to system 100, the stacked memory device 104, application specific integrated circuit 120, a host device, or a combination thereof. In certain embodiments, the machine may be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment. In certain embodiments, the machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

In certain embodiments, the exemplary computer system 800 may include a processing device 802, a main memory 804 (e.g., read-only memory (ROM), flash memory, dynamic random-access memory (DRAM) such as synchronous DRAM (SDRAM) or Rambus DRAM (RDRAM), static random-access memory (SRAM), etc.), and/or a data storage system 818, which are configured to communicate with each other via a bus 830 (which can include multiple buses). In certain embodiments, processing device 802 may represent one or more general-purpose processing devices such as a microprocessor, a central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets, or processors implementing a combination of instruction sets. In certain embodiments, the processing device 802 may also be one or more special-purpose processing devices such as an application specific integrated circuit (ASIC), a field programmable gate array (FPGA), a digital signal processor (DSP), network processor, or the like.

The processing device 802 is configured to execute instructions 826 for performing the operations and steps discussed herein. For example, the processing device 802 may be configured to perform steps supporting the functionality provided by the system 100, the stacked memory die 102, the application specific integrated circuit 120, any other componentry in the Figures, or a combination thereof. For example, in certain embodiments, the computer system 800 may be configured assist in requesting a write to the stacked memory die 104, requesting a read of data stored in the stacked memory die 104, requesting an erasure of data stored in the stacked memory die 104, facilitating communications between the application specific integrated circuit 120 and the stacked memory die 104, performing any other operations as described herein, or a combination thereof. As another example, in certain embodiments, the computer system 800 may assist with conducting the operative functionality of the controller 114, the interface shim layer 110, or a combination thereof. In certain embodiments, computer system 800 may further include a network interface device 808 to communicate over a network 820.

The data storage system 818 can include a machine-readable storage medium 824 (also referred to as a computer-readable medium herein) on which is stored one or more sets of instructions 826 or software embodying any one or more of the methodologies or functions described herein. The instructions 826 can also reside, completely or at least partially, within the main memory 804 and/or within the processing device 802 during execution thereof by the computer system 800, the main memory 804 and the processing device 802 also constituting machine-readable storage media. The machine-readable storage medium 824, data storage system 818, and/or main memory 804 can correspond to the system 100, the stacked memory die 104, or a combination thereof.

Reference in this specification to “one embodiment” “an embodiment” or “certain embodiments” may mean that a particular feature, structure, or characteristic described in connection with the embodiment is included in at least one embodiment of the disclosure. The appearances of the phrases “in one embodiment” and “in certain embodiments” in various places in the specification are not necessarily all referring to the same embodiment(s), nor are separate or alternative embodiments mutually exclusive of other embodiments. Moreover, various features are described which may be exhibited by some embodiments and not by others. Similarly, various requirements are described which may be requirements for some embodiments, but not other embodiments.

Although some of the drawings illustrate a number of operations in a particular order, operations which are not order dependent may be reordered and other operations may be combined or broken out. While some reordering or other groupings are specifically mentioned, others will be apparent to those of ordinary skill in the art and so do not present an exhaustive list of alternatives. Moreover, it should be recognized that the stages could be implemented in hardware, firmware, software or any combination thereof.

In the foregoing specification, the disclosure has been described with reference to specific exemplary embodiments thereof. It will be evident that various modifications may be made thereto without departing from the broader spirit and scope as set forth in the following claims. The specification and drawings are, accordingly, to be regarded in an illustrative sense rather than a restrictive sense.

What is claimed is:

1. A memory device, comprising:
a plurality of stacked memory die; and
an interface shim layer;
wherein the interface shim layer is directly coupled to at least one memory die of the plurality of stacked memory die;
wherein the interface shim layer is configured to directly couple to an application specific integrated circuit; and
wherein the interface shim layer is configured to facilitate communication between the plurality of stacked memory die and the application specific integrated circuit via a routing layer of the interface shim layer.

2. The memory device of claim 1, wherein the interface shim layer further comprises a through-silicon via configured to serve as an interconnect between the interface shim layer and the plurality of stacked memory die.

3. The memory device of claim 1, wherein the interface shim layer comprises a plurality of wires configured to facilitate coupling of the plurality of stacked memory die to the application specific integrated circuit via the interface shim layer.

4. The memory device of claim 1, wherein the memory device further comprises a plurality of bumps configured to interconnect at least one memory die of the plurality of stacked memory die with at least one other memory die of the plurality of stacked memory die.

5. The memory device of claim 1, wherein the interface shim layer is further configured to communicate with the application specific integrated circuit via a physical interface layer of the application specific integrated circuit.

6. The memory device of claim 1, wherein the memory device further comprises a package substrate comprising silicon upon which the plurality of stacked memory die, the interface shim layer, and the application specific integrated circuit are disposed.

7. The memory device of claim 1, wherein the interface shim layer is further configured to include a first physical interface configured to include input output circuits configured to communicate with the plurality of stacked memory die.

8. The memory device of claim 7, wherein the interface shim layer is further configured to include a second physical interface configured to communicate with the application specific integrated circuit.

9. A memory device, comprising:
a plurality of stacked memory die; and
an interface shim layer;
wherein the interface shim layer is directly coupled to at least one memory die of the plurality of stacked memory die and comprises a first physical interface configured to facilitate communication to and from the plurality of stacked memory die; and
wherein the interface shim layer comprises a second physical interface configured to facilitate communication to and from an application specific integrated circuit, wherein the interface shim layer is configured to directly couple to the application specific integrated circuit.

10. The memory device of claim 9, wherein the interface shim layer further comprises a plurality of routing layers configured to facilitate communication between the first physical interface and the second physical interface.

11. The memory device of claim 9, wherein the interface shim layer further comprises a plurality of through silicon vias configured to facilitate communication with the plurality of stacked memory die.

12. The memory device of claim 9, wherein the second physical interface is configured to facilitate communication with the application specific integrated circuit and the second physical interface via a plurality of through silicon vias.

13. The memory device of claim 9, wherein the interface shim layer further comprises a memory controller configured to manage communication and control the plurality of stacked memory die.

14. The memory device of claim 13, wherein the memory controller is configured to provide a scheduler function, timing control, memory refresh management, data first-in first-outs, error correction, floor sweeping, reliability, availability, and serviceability functionality, or a combination thereof.

15. The memory device of claim 9, wherein the interface shim layer further comprise a built-in self-test circuit configured to test functionality of the plurality of stacked memory die, repair the plurality of stacked memory die, or a combination thereof.

16. The memory device of claim 9, wherein the first physical interface comprises a plurality of input output circuits that are configured to communicate with the plurality of stacked memory die.

17. The memory device of claim 9, wherein the second physical interface comprises a plurality of input output circuits that are configured to communicate with the application specific integrated circuit.

18. The memory device of claim 9, wherein the plurality of stacked memory die comprise tightly-controlled random access memory die.

19. The memory device of claim 9, wherein the memory device further comprises a plurality of bumps configured to interconnect the plurality of stacked memory die.

20. A method, comprising
stacking a plurality of memory die to form a stacked memory die;
directly coupling the stacked memory die to an interface shim layer, wherein the interface shim layer comprises a first through-silicon via and a routing layer configured to facilitate routing of signals from the stacked memory die; and
directly coupling the interface shim layer to an application specific integrated circuit, wherein the routing layer is configured to facilitate routing of the signals from the stacked memory die to the application specific integrated circuit via a second through-silicon via.
